(19) United States
(12) Patent Application Publication
(10) Pub. No.: US 2008/0153304 A1
(43) Pub. Date: Jun. 26, 2008

(54) METHOD OF PRODUCING A SEMICONDUCTOR DEVICE

(75) Inventor: Yasuhiko Ueda, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: ELPIDA MEMORY, INC., Tokyo (JP)

(21) Appl. No.: 11/955,885

(22) Filed: Dec. 13, 2007

(30) Foreign Application Priority Data
Dec. 20, 2006 (JP) 2006-342143

(51) Int. Cl. H01L 21/302

(52) U.S. Cl. 438/706; 257/E21.54

(57) ABSTRACT

In a method of producing a semiconductor device, semiconductor burrs (74) are removed by dry etching using an etching gas in which a lateral-direction etch rate (R2) is greater than a depth-direction etch rate (R1) (that is, R1/R2 is smaller than 1) in a section of a groove (72) in a direction parallel to word lines.

This application is based upon and claims the benefit of priority from prior Japanese patent application JP 2006-342143, filed on Dec. 20, 2006, the disclosure of which is incorporated herein by reference in its entirety.

### BACKGROUND OF THE INVENTION

This invention relates to a method of producing a semiconductor device and, in particular, to a method of producing a semiconductor device having a trench gate.

For example, recent miniaturization of a DRAM (Dynamic Random Access Memory) is remarkable. Following the miniaturization of the DRAM, a gate of a transistor in a memory cell inside the DRAM is also miniaturized. Following the miniaturization of the gate, the problem of a short-channel effect of the transistor is exposed. Under the circumstances, the technique called a “trench gate” becomes a mainstream in which a groove (trench) is formed under the gate and the bottom of the groove is used as a channel so as to assure a sufficient and necessary channel length. In the “trench gate”, there is a problem of high Si burrs produced in the groove in a direction parallel to word lines (i.e., parallel to gate electrodes) during formation of the groove. In detail, the Si burrs are produced in the groove on a surface adjacent to STI (Shallow Trench Isolation).

In the existing technique, the Si burrs are removed by oxidizing the Si burrs into an oxide film and then wet-etching the oxide film, as will be described below as the related art. In this method, however, the amount of oxidization and the amount of wet etching must be increased depending upon the thickness of the burrs. Excessive wet etching results in a difference in surface levels, causing a serious influence.

Referring to FIGS. 1 to 10, the technique of forming the trench gate as the related art will be described.

Referring to FIG. 1, a STI buried oxide film 20 of SiO₂ is formed on a silicon substrate 10. In an active region forming area 30 where an active region of a memory cell is to be formed later, a thin oxide film 21 of SiO₂ is formed on the silicon substrate 10.

On the oxide film 21 on the silicon substrate 10 and on the STI buried oxide film 20, a SiN (silicon nitride) film (will later be illustrated) of Si₃N₄ is formed. A part of the SiN film is selectively removed by dry etching in a normal gate forming region 50 where a normal gate region of the memory cell is to be formed later. Consequently, the oxide film 21 on the silicon substrate 10 is exposed. This state is illustrated in FIG. 2. In FIG. 2, the remaining part of the SiN film left after the dry etching is depicted by a reference numeral 40.

Referring to FIG. 3, on the exposed oxide film 21 on the silicon substrate 10 and on the SiN film 40, a sidewall-forming SiN film 60 of Si₃N₄ is formed.

Referring to FIG. 4, a part of the sidewall-forming SiN film 60 is selectively removed by etching in a trench gate forming region 70 where a trench gate region of the memory cell is to be formed later. The remaining part of the sidewall-forming SiN film 60 is left as a sidewall.

Referring to FIG. 5, with the SiN film 40 and the SiN film 60 (sidewall) used as a mask, the oxide film 21 in the trench gate forming region 70 and the silicon substrate 10 are dry etched to form a trench (groove) 72. At this time, Si burrs 74 are produced in a direction parallel to word lines (i.e., parallel to gate electrodes as described above). Specifically, the Si burrs 74 are produced in the trench (groove) 72 on a surface adjacent to the STI buried oxide film 20.

Herein, the reason why the Si burrs 74 are produced will be described.

Turning back to FIG. 4, attention will be directed to a part A. Although this figure is simplified, corners of a surface of the active region forming area 30 are intentionally rounded actually. The oxide film (SiO₂ film) is formed also on the Si substrate 10 thus rounded. Therefore, silicon directly under the oxide film (SiO₂ film) is left as the Si burrs 74 (FIG. 5).

Next, attention will be directed to a part B in FIG. 4. Silicon in the active region forming area 30 has a tapered shape. The tapered shape is required for stress relaxation. Therefore, even if the silicon substrate 10 is straightly cut by dry etching, silicon is left as the Si burrs 74 (FIG. 5) in correspondence to the tapered shape.

Thus, the Si burrs are left because of the above-mentioned two reasons.

When the Si burrs are left unremoved, a parasitic channel is formed to cause a hump phenomenon. Therefore, the Si burrs must be removed.

Referring to FIG. 6, in order to remove the Si burrs 74 (FIG. 5), at first, an inner surface of the trench 72 is sacrificially oxidized to sacrificially oxidize the Si burrs. Thus, a sacrificial oxide film 80 of SiO₂ is formed on the inner surface of the trench 72. Subsequently, the SiN film 40 and the SiN film 60 (sidewall) are removed by wet etching. Then, the state illustrated in FIG. 7 is obtained.

Next referring to FIG. 7, the sacrificial oxide film 80 is removed by wet etching. As illustrated in FIG. 8, the trench 72 is exposed. At this time, as illustrated in FIG. 8, a step 22 may be formed in the STI buried oxide film 20 by scraping or shaving.

Next referring to FIG. 9, a gate oxide film 90 of SiO₂ is formed on the inner surface of the trench 72 in the active region forming region 30. Then, referring to FIG. 10, a gate DOPOS (Doped poly-silicon) 96, which will later be formed into gate electrodes (word lines) 95-1 and 95-2, is formed. At this time, because of presence of the step 22 in the STI buried oxide film 20, undulation 97 is produced in the gate DOPOS 96.

As described above, in the existing technique, the Si burrs 74 produced upon formation of the trench 72 by dry etching as shown in FIG. 5 are removed by oxidization (thermal oxidization). As the burrs are greater, the amount of oxidization is increased correspondingly. The increase in amount of oxidization results in an increase in amount of SiO₂ etching in wet etching of the oxide film after the oxidization. When the amount of SiO₂ etching is increased, the SiO₂ scraped portion (step 22 in FIG. 8) on the STI is enlarged. When the SiO₂ scraped portion (step 22 in FIG. 8) on the STI is enlarged, there arises a problem of increase in word line capacitance (part X in FIG. 10) and so one.

Japanese Unexamined Patent Application Publication No. 2004-087738 (JP-A) (Patent Document 1) discloses use of a mixed gas of SF₆/O₂/SiF₄ as an etching gas for trench etching of a Si substrate (see Example 2).

Japanese Unexamined Patent Application Publication No. H06-163478 (JP-A) (Patent Document 2) discloses use of a mixed gas of SF₆/HBr as an etching gas upon forming a trench in a silicon substrate by etching (see Comparative Example 2 in FIG. 4).

### SUMMARY OF THE INVENTION

As described above, in order to remove the Si burrs, the existing technique adopts the method including thermal oxidization of the Si burrs and wet etching of the oxide film. However, in order to completely remove the Si burrs which are thick and high, the thermal oxidization and the wet etching of the oxide film must be excessively carried out. This results in recession of the STI oxide film and occurrence of a step on a surface. As a consequence, there arises a problem of increase in word line capacitance. Under the circumstances, there is a demand for a method of removing Si burrs using other means.

It is an exemplary object of this invention to provide a method of producing a semiconductor device capable of removing semiconductor burrs without causing an increase in word line capacitance.

It is another exemplary object of this invention to provide a method of producing a semiconductor device capable of preventing occurrence of semiconductor burrs without causing an increase in word line capacitance.

Methods according to this invention are as follows:

(1) A method of producing a semiconductor device, comprising an etching step of dry etching a semiconductor substrate by the use of an etching gas in which an etch rate in a lateral direction is greater than an etch rate in a depth direction.

(2) The method according to the above-mentioned (1), further comprising:

a STI (Shallow Trench Isolation) forming step of forming a STI layer on a surface of the semiconductor substrate and a groove forming step of forming a groove for a trench gate by dry etching on the surface of the semiconductor substrate in an area surrounded by the STI layer;

the etching step being a step of dry etching, by the use of the etching gas, the semiconductor substrate with the groove formed thereon.

(3) The method according to the above-mentioned (2), wherein:

the etching step is a step intended to remove semiconductor burrs produced in the groove on groove surfaces adjacent to the STI layer during formation of the groove on the surface of the semiconductor substrate;

the etching step being a step of removing the semiconductor burrs by dry etching using, as the etching gas, a mixed gas having a gas flow rate ratio such that an etch rate ratio R1/R2 is smaller than 1, where R1 is the etch rate in the depth direction in a section of the groove in a direction parallel to word lines and R2 is the etch rate in the lateral direction in the section of the groove in the direction parallel to the word lines;

the mixed gas consisting essentially of SF₆ and SiF₄.

(4) The method according to the above-mentioned (2), wherein:

the etching step is a step intended to remove semiconductor burrs produced in the groove on groove surfaces adjacent to the STI layer during formation of the groove on the surface of the semiconductor substrate;

the etching step being a step of removing the semiconductor burrs by dry etching using, as the etching gas, a mixed gas having a gas flow rate ratio such that an etch rate ratio R1/R2 is smaller than 1, where R1 is the etch rate in the depth direction in a section of the groove in a direction parallel to word lines and R2 is the etch rate in the lateral direction in the section of the groove in the direction parallel to the word lines and that an etch rate ratio R3/R4 is equal to or greater than 1, where R3 represents an etch rate in a depth direction in a section of the groove in a direction perpendicular to the word lines and R4 represents an etch rate in a lateral direction in the section of the groove in the direction perpendicular to the word lines;

the mixed gas consisting essentially of SF₆ and SiF₄.

(5) A method of producing a semiconductor device, comprising a STI (Shallow Trench Isolation) forming step of forming a STI layer on a surface of a semiconductor substrate and a groove forming step of forming a groove for a trench gate by dry etching on the surface of the semiconductor substrate in an area surrounded by the STI layer wherein:

the groove forming step is a step of forming the groove in the area by dry etching using a mixed gas consisting essentially of SF₆ and HBr without producing semiconductor burrs in the groove on groove surfaces adjacent to the STI layer.

(6) The method according to claim 5, wherein the groove forming step uses, as the mixed gas, a mixed gas having a gas flow rate ratio FR satisfying:

0.2<FR<4

where FR is given by (SF₆ flow rate)/(HBr flow rate).

The above-referred Patent Documents 1 and 2 do not disclose that, upon forming a groove for a trench gate, Si burrs are produced in the groove on a surface adjacent to a STI buried oxide film and that an etching gas, in which an etch rate in a lateral direction is greater than an etch rate in a depth direction, is used in order to remove the Si burrs. Further, the Patent Documents 1 and 2 do not disclose that an etching gas is used which has a SF₆/SiF₄ gas flow rate ratio (mixing ratio) such that the etch rate in the lateral direction is greater than the etch rate in the depth direction. Still further, the Patent Documents 1 and 2 do not disclose prevention of occurrence of the Si burrs upon forming the groove for the trench gate and a specific SF₆/HBr gas flow rate ratio capable of preventing occurrence of the Si burrs.

In this invention, dry etching is performed by the above-mentioned composition containing SF₆ as an isotropic etching component and SiF₄ as a deposition gas added thereto. Thus, without damaging or deforming the shape of the groove, the Si burrs produced in the groove on the surface adjacent to the STI layer can be removed. Accordingly, no increase in capacitance occurs unlike the above-mentioned related art.

Further, in this invention, dry etching is performed by the above-mentioned composition containing SF₆ as an isotropic etching component and HBr generating a low vapor pressure etching product. Thus, the groove can be formed on the surface of the semiconductor substrate without producing Si burrs in the groove on the surface adjacent to the STI layer. Again, no increase in capacitance occurs unlike the above-mentioned related art.

### BRIEF DESCRIPTION OF THE DRAWINGS

FIG. 1 is view for describing a first step in an existing trench gate forming technique;

FIG. 2 is a view for describing a second step following the first step in FIG. 1;

FIG. 3 is a view for describing a third step following the second step in FIG. 2;

FIG. 4 is a view for describing a fourth step following the third step in FIG. 3;

FIG. 5 is a view for describing a fifth step following the fourth step in FIG. 4;

FIG. 6 is a view for describing a sixth step following the fifth step in FIG. 5;

FIG. 7 is a view for describing a seventh step following the sixth step in FIG. 6;

FIG. 8 is a view for describing an eighth step following the seventh step in FIG. 7;

FIG. 9 is a view for describing a ninth step following the eighth step in FIG. 8;

FIG. 10 is a view for describing a tenth step following the ninth step in FIG. 9;

FIG. 11 is a view for describing a first embodiment of this invention;

FIG. 12 is a view for describing the first embodiment;

FIG. 13 is a view for describing the first embodiment (Example 1);

FIG. 14 is a view for describing a second embodiment (Example 3) according to this invention; and

FIG. 15 is a view for describing the second embodiment (Example 3).

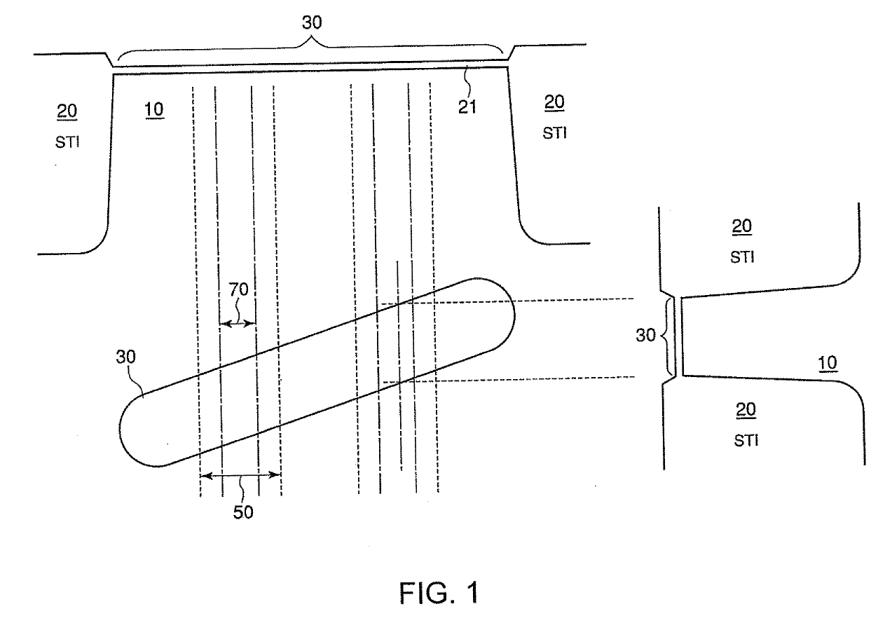

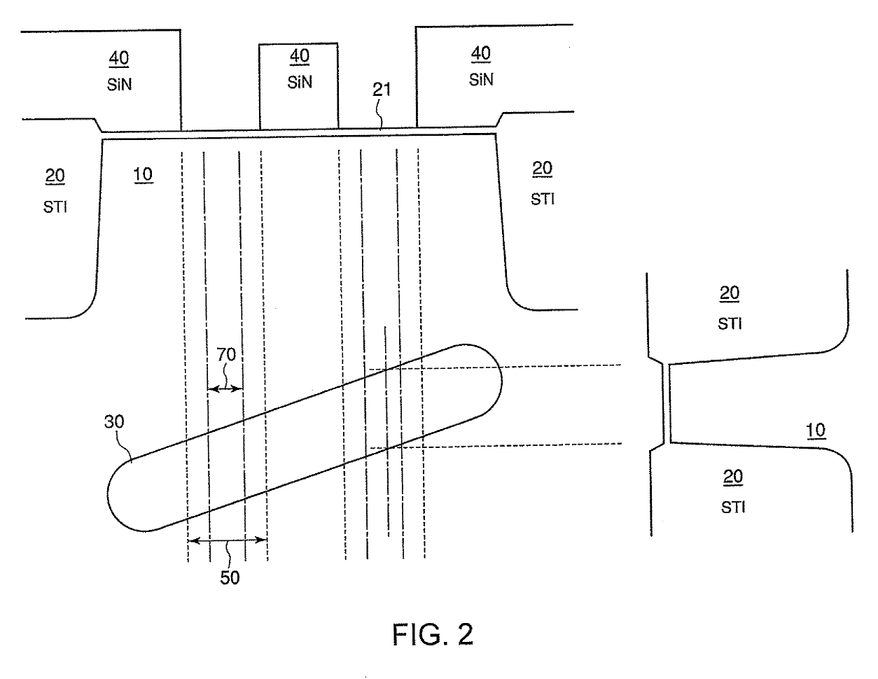

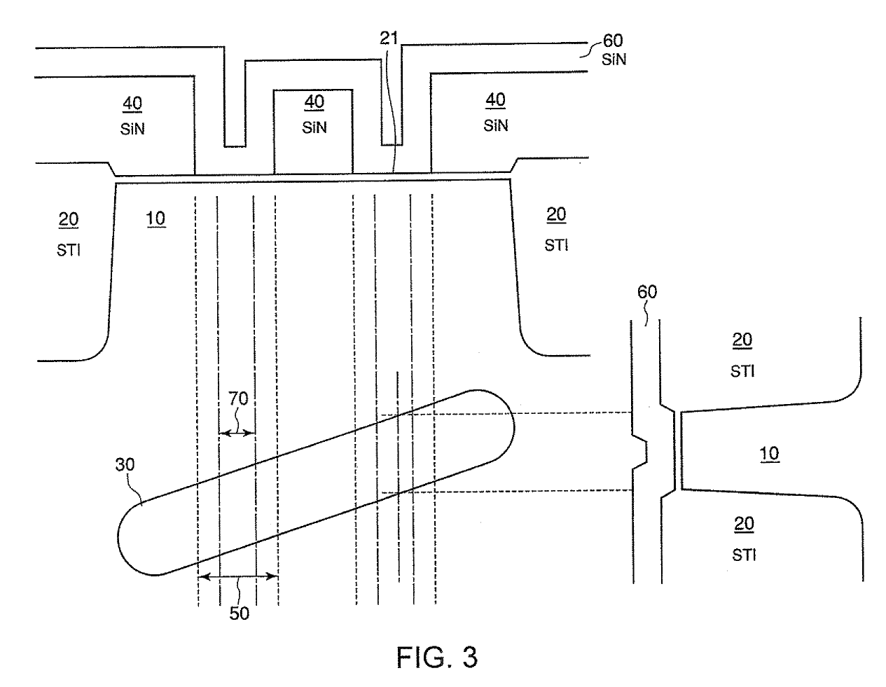

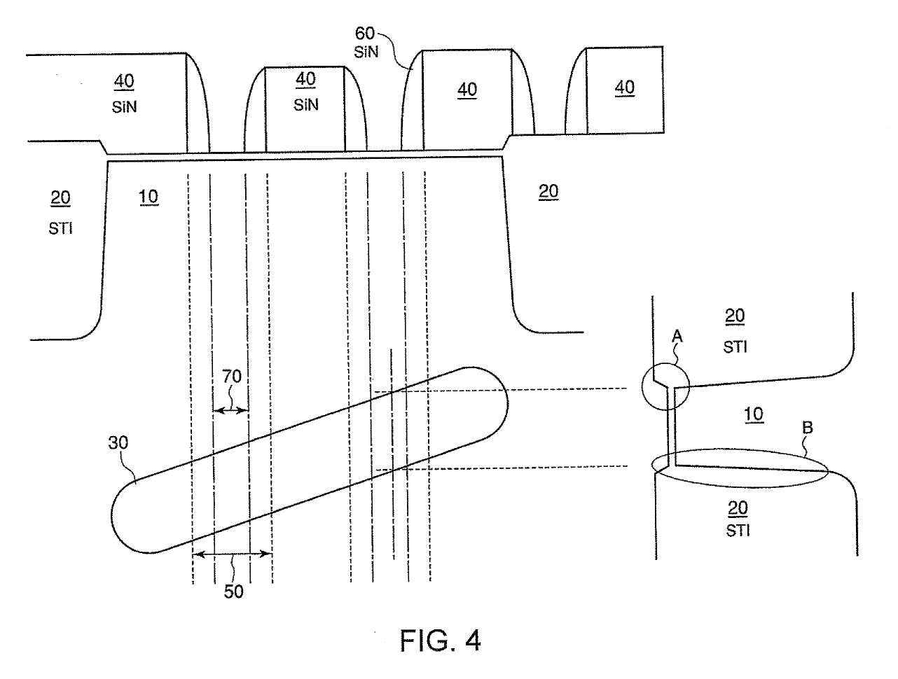

### DESCRIPTION OF THE EXEMPLARY EMBODIMENTS

Now, this invention will be described with reference to the drawing.

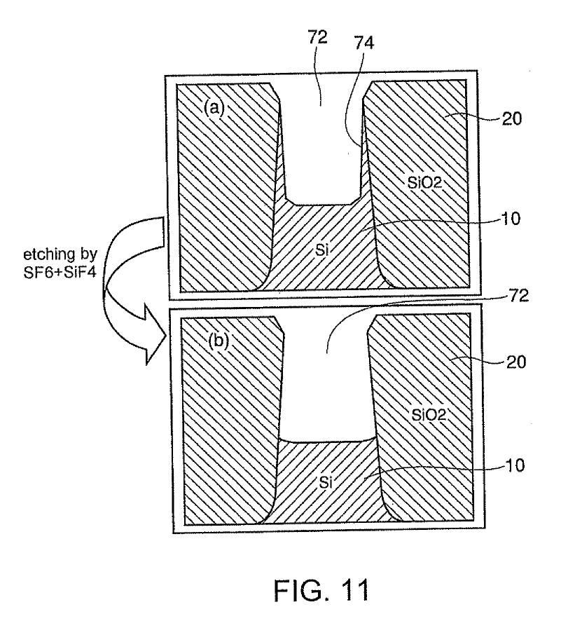

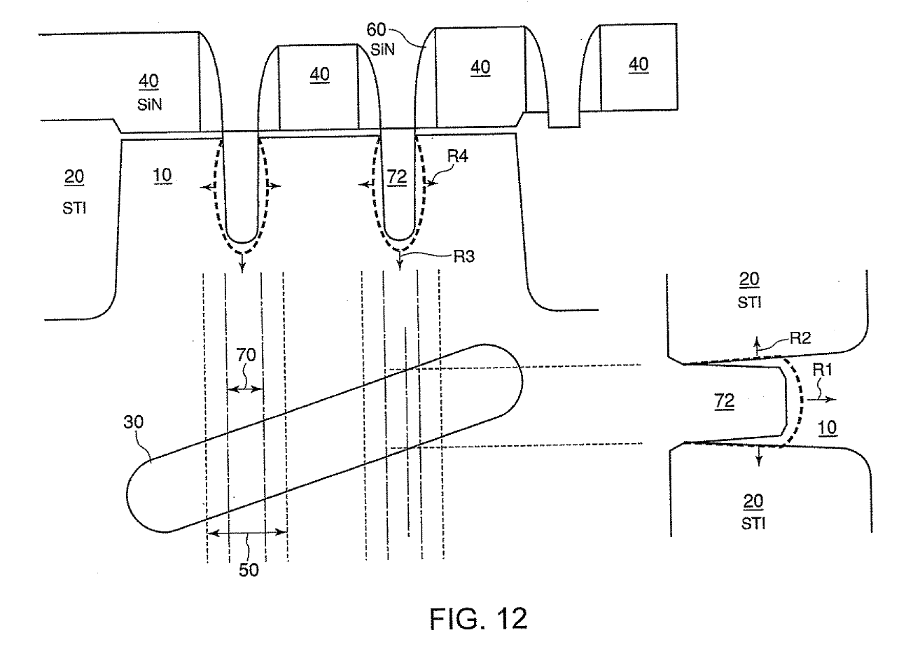

Referring to FIGS. 11 and 12, a first embodiment of this invention will be described. In the first embodiment, an etching gas in which an etch rate in a lateral direction is greater than an etch rate in a depth direction is produced by a composition containing SF₆ as an isotropic etching component and SiF₄ as a deposition gas added thereto (the specific numerical values of gas flow rates will be described later). In the first embodiment, an etching step of dry etching a semiconductor substrate by the use of the etching gas is carried out. In this manner, without damaging or deforming the shape of a groove 72 or a STI buried oxide film 20, Si burrs 74 ((a) in FIG. 11) produced in the groove 72 on a surface adjacent to the STI buried oxide film 20 are efficiently removed ((b) in FIG. 11). In the etching step, while isotropic etching is performed by a radical etching effect due to SF₆, a round shape inherent to the isotropic etching is changed into a substantially flat shape. Thus, a bottom surface of the groove 72 can be formed into a flat shape while the isotropic etching is performed. This is because a physical property that SiF₄ used as the deposition gas has a relatively low adsorption probability and a nature that deposition is easily made in an area where progress of etching is easy are successfully utilized.

Thus, a method of producing a semiconductor device comprises an etching step of dry etching a semiconductor substrate by the use of an etching gas in which a lateral-direction etch rate (that is, an etch rate in a lateral direction) is greater than a depth-direction etch rate (that is, an etch rate in a depth direction).

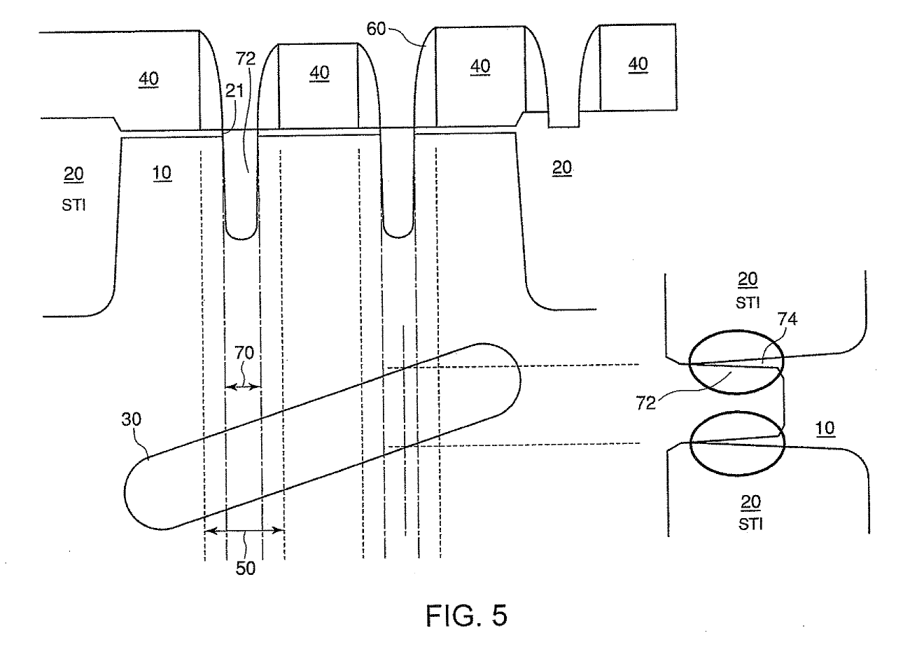

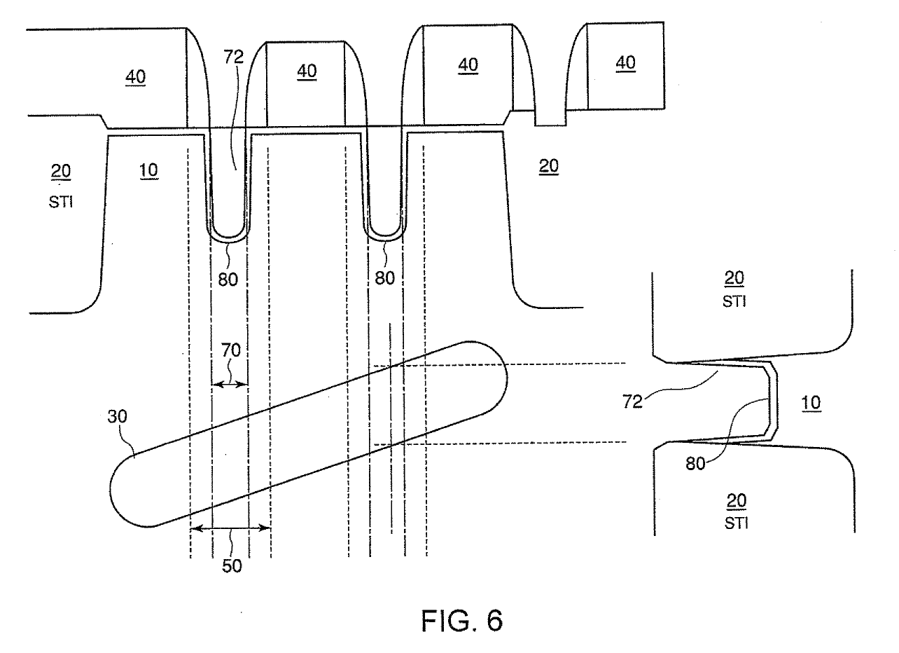

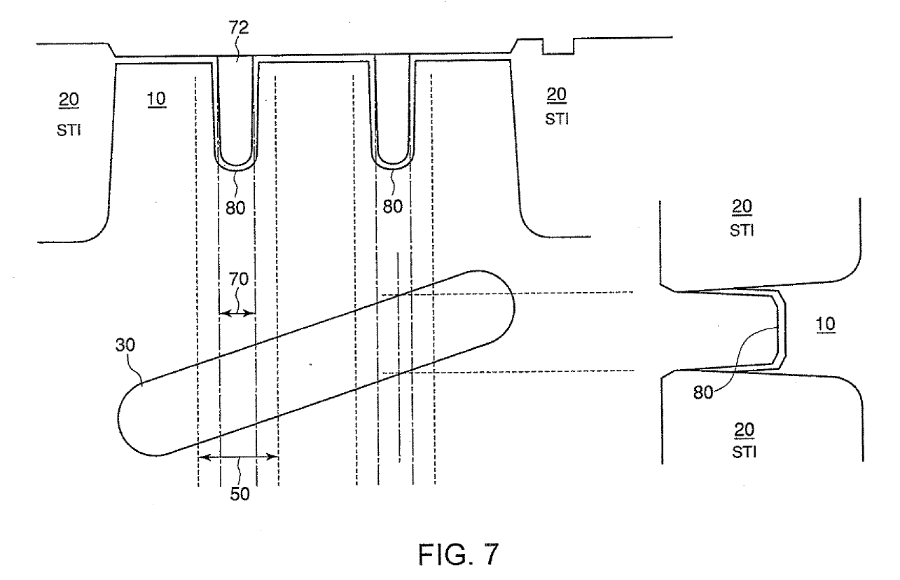

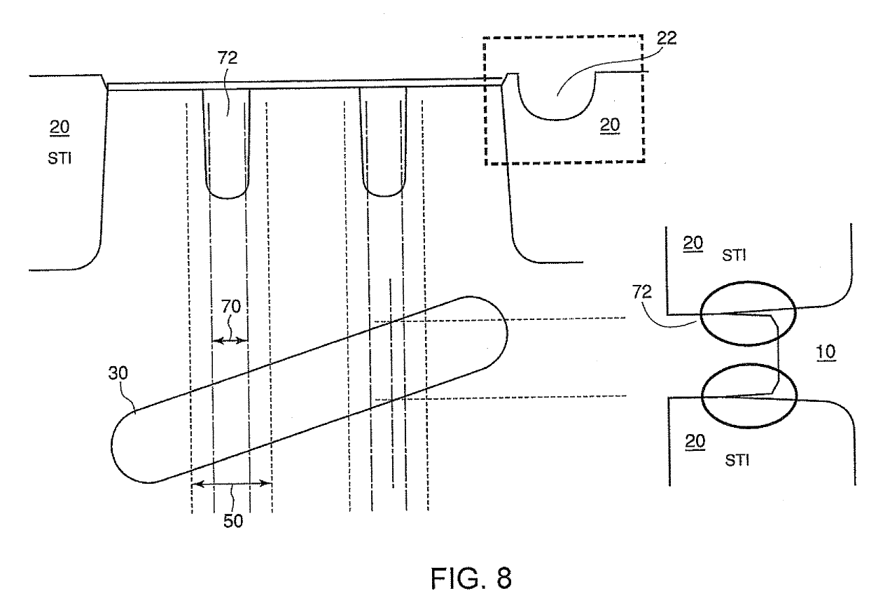

In detail, dry etching using the above-mentioned composition containing SF₆ and SiF₄ added thereto is carried out as a step illustrated in FIG. 12 and following the step illustrated in FIG. 5.

Referring to FIG. 12, the Si burrs 74 are removed by dry etching using a mixed gas containing SF₆ and SiF₄ and having a gas flow rate ratio such that an etch rate ratio R1/R2 is smaller than 1 where R1 represents a depth-direction etch rate in a section of the groove 72 in a direction parallel to word lines (i.e., a direction parallel to gate electrodes as described above) and R2 represents a lateral-direction etch rate in the section of the groove 72 in the direction parallel to the word lines.

Preferably, the Si burrs 74 are removed by dry etching using a mixed gas containing SF₆ and SiF₄ and having a gas flow rate ratio such that an etch rate ratio R1/R2 is smaller than 1 where R1 represents a depth-direction etch rate in a section of the groove 72 in a direction parallel to word lines (i.e., a direction parallel to gate electrodes as described above) and R2 represents a lateral-direction etch rate in the section of the groove 72 in the direction parallel to the word lines and that an etch rate ratio R3/R4 is equal to or greater than 1 where R3 represents a depth-direction etch rate in a section of the groove 72 in a direction perpendicular to the word lines (i.e., a direction perpendicular to the gate electrodes) and R4 represents a lateral-direction etch rate in the section of the groove 72 in the direction perpendicular to the word lines.

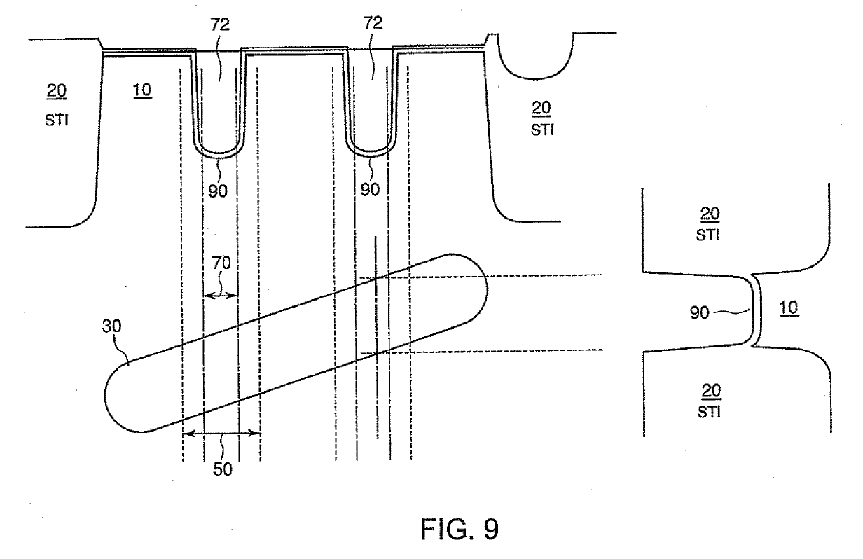

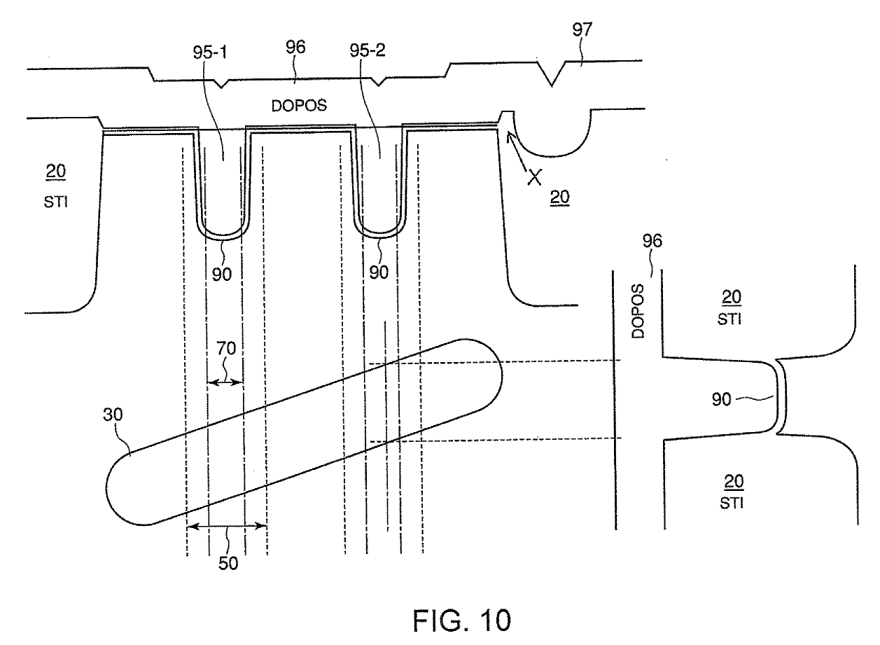

When the abovementioned burr removing step in FIG. 12 is finished, a gate oxide film forming step in FIG. 9 and a step in FIG. 10 are carried out. Referring to FIG. 10, a gate DOPOS (Doped poly-silicon) 96, which will later be formed into gate electrodes (word lines) 95-1 and 95-2, is formed. In this invention, no step 22 is formed in the STI buried oxide film 20. Therefore, no undulation 97 is formed in the gate DOPOS 96 so that no increase in word line capacitance (part X in FIG. 10) is caused.

In a second embodiment of this invention, dry etching is performed by the use of a composition containing SF₆ as an isotropic etching component and HBr generating a low vapor pressure etching product (specific numerical values of gas flow rates will later be described). Thus, as illustrated in (b) in FIG. 11, the groove 72 can be formed on the surface of the semiconductor substrate without producing Si burrs in the groove 72 on a surface adjacent to the STI buried oxide film 20. Thus, as a result of forming the groove 72 by the use of the above-mentioned composition containing SF₆ and HBr added thereto, the bottom surface of the groove 72 is formed by Si while side surfaces of the groove 72 are formed by the STI buried oxide film 20.

Specifically, the dry etching using the above-mentioned composition containing SF₆ and HBr added thereto is carried out as the step in FIG. 5. After the dry etching, the gate oxide film forming step in FIG. 9 and the step in FIG. 10 are carried out. In this case, no Si burrs are produced. Therefore, the step 22 in the STI buried oxide film 20, the undulation 97 in the gate DOPOS 96, and the increase in word line capacitance (part X in FIG. 10), which are shown in FIG. 10, are not caused.

Now, examples of this invention will be described.

### Example 1

In Example 1, a SF₆/SiF₄ gas mixing ratio capable or efficiently removing Si burrs is determined.

This example is for use in implementing the first embodiment.

The burr removing step is required to meet the following requirements:

(1) the lateral-direction etch rate R2 is as higher as possible than the depth-direction etch rate R1 in the section of the groove 72 in the direction parallel to the word lines in FIG. 12; and

(2) microloading is large and the etch rate is low with respect to a fine pattern.

In order to determine an appropriate condition satisfying these requirements, an experimental test is carried out.

A basic condition is as follows.

SF₆/SiF₄/O₂=50/180/5(sccm), 4 Pa, 15 sec

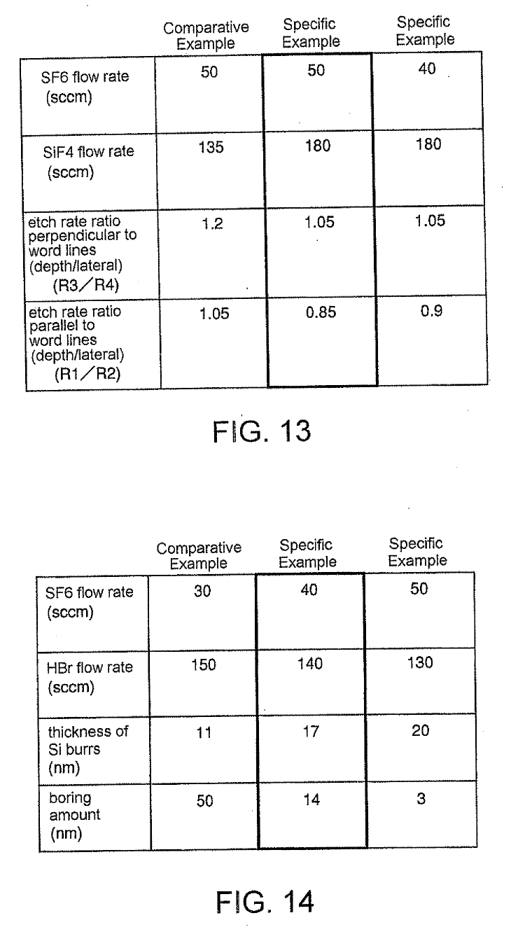

Examination has been made about the relationship between the SF₆/SiF₄ flow rate and the ratio of the depth-direction etch rate and the lateral-direction etch rate. FIG. 12 shows the depth-direction etch rate R1 and the lateral-direction etch rate R2 in the section of the groove 72 in the direction parallel to the word lines as well as the depth-direction etch rate R3 and the lateral-direction etch rate R4 in the section of the groove 72 in the direction perpendicular to the word lines. The results are shown in FIG. 13.

From the result illustrated in FIG. 13, among the etch rate ratios in the section of the groove 72 in the direction parallel to the word lines, the ratio (R1/R2) of the depth-direction etch rate and the lateral-direction etch rate is smallest, i.e., the Si burr removing efficiency is highest, when the gas flow rate ratio is SF₆/SiF₄=50/180 (sccm). In case where the gas flow rate ratio is SF₆/SiF₄=40/180 (sccm), the ratio (R1/R2) of the depth-direction etch rate and the lateral-direction etch rate is smaller than 1. Therefore, this example is taken as a specific example of this invention. On the other hand, when the gas flow rate ratio is SF₆/SiF₄=50/135 (sccm), the ratio of the depth-direction etch rate and the lateral-direction etch rate is greater than 1. Therefore, this example is taken as a comparative example. For the etch rate ratio in the section of the groove 72 in the direction perpendicular to the word lines, the ratio (R3/R4) of the depth-direction etch rate and the lateral-direction etch rate is 1.05 which is greater than 1 in the specific examples. In this invention, this ratio (R3/R4) may be equal to 1. Thus, in this invention, the ratio (R3/R4) is not smaller than 1. The lateral-direction etch rate in the section perpendicular to the word lines is small because the aspect ratio is high and an etchant is difficult to enter.

In this example, etching was carried out at 60° C. It is found out that, by changing the temperature in a range from −5° C. to 150° C., the etch rate ratio can be controlled with a certain degree of freedom.

### Example 2

In Example 2, Si burrs produced during formation of the groove using a HBr/Cl₂/O₂ gas are removed by dry etching under the condition determined in Example 1.

This example is also used for implementing the first embodiment.

At first, a field (STI buried oxide film) is formed. Thereafter, using a mask of a reversed gate pattern, a groove having a depth of 150 nm is formed in a Si substrate by a HBr/Cl₂/O₂ gas. An etching apparatus is a commercially-sold ICP (Inductive Coupled Plasma) etching apparatus. The etching condition is as follows (typical STI silicon etching condition).

Cl₂/HBr/O₂=90/80/5(sccm), 4 Pa, 15 sec

At this time, the Si burrs produced in the direction parallel to the word lines have a height of 115 nm and a base thickness of 30 nm. By carrying out the etching step of removing Si burrs as optimized in Example 1, the Si burrs in the direction parallel to the word lines could be removed substantially without damaging or deforming the shape of the groove in the direction perpendicular to the word lines. After removing the Si burrs, the bottom of the groove has a slightly rounded shape. However, after gate formation, the bottom is substantially flat. Therefore, a factor disturbing transistor characteristics, such as hump, is not caused.

### Example 3

In Example 3, groove Si etching without occurrence of Si burrs is carried out by the use of a SF₆/HBr gas.

This example is used for implementing the second embodiment.

From the result of Example 2, the function of adjusting the shape of the bottom of the groove by isotropic etching using SF₆ and deposition using SiF₄ has been confirmed. Therefore, consideration is next made about a technique of performing groove Si etching without producing the Si burrs. As a gas for use with SF₆, SiF₄ is insufficient in vertical etching rate. Therefore, a HBr gas is used herein which serves as a vertical etching gas and generates an etching product having a relatively low vapor pressure. The etching condition is as follows. Optimization of a gas mixing ratio alone was carrier out.

SF₆/HBr=40/140(sccm), 1 Pa, 20 sec (center condition)

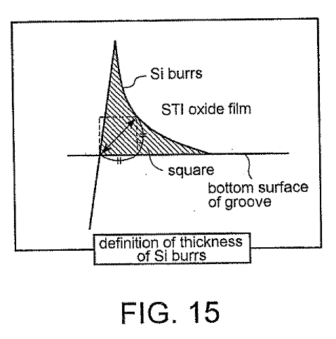

Herein, as evaluation items, the thickness of the Si burrs and a boring amount in the direction perpendicular to the word lines are selected. The result of test is shown in FIG. 14. Boring is a phenomenon that a center part of the groove is side-etched. The boring amount is represented by a difference between this part and an opening width. The definition of the thickness of the Si burrs and a measuring method are shown in FIG. 15. From the result in FIG. 14, the thickness of the Si burrs is thinnest at the flow rate ratio SF₆/HBr=30/150 (sccm). However, boring in the direction perpendicular to the word lines is significantly large. Therefore, this condition is taken as a comparative example.

The optimum value is judged as SF₆HBr=40/140 (sccm). The ratio of SF₆/HBr=50/130 (sccm) is also adoptable as a specific example.

Assembling the above-mentioned test results and other test results with respect to the flow rate ratio, an appropriate range of the flow rate ratio is determined. Herein, the flow rate ratio (SF₆ flow rate)/(HBr flow rate) is represented by FR. By dry etching using a mixed gas having the gas flow rate ratio FR in the following range, the groove 72 can be formed on the surface of the semiconductor substrate without producing Si burrs in the groove 72 on the surface adjacent to the STI buried oxide film 20.

0.2<FR<0.4

The similar test was carried out in case where SiF₄ was used instead of HBr. Depending upon the condition, this mixed gas is usable. However, in case of SiF₄, the vertical etch rate is insufficient. Therefore, the etching time is inevitably lengthened to cause some disadvantage.

Although this invention has been described in conjunction with a few exemplary embodiments thereof this invention may be modified in various other manners.

What is claimed is:

1. A method of producing a semiconductor device, comprising an etching step of dry etching a semiconductor substrate by the use of an etching gas in which an etch rate in a lateral direction is greater than an etch rate in a depth direction.

2. The method according to claim 1, further comprising:
a STI (Shallow Trench Isolation) forming step of forming a STI layer on a surface of the semiconductor substrate and a groove forming step of forming a groove for a trench gate by dry etching on the surface of the semiconductor substrate in an area surrounded by the STI layer;
the etching step being a step of dry etching, by the use of the etching gas, the semiconductor substrate with the groove formed thereon.

3. The method according to claim 2, wherein:
the etching step is a step intended to remove semiconductor burrs produced in the groove on groove surfaces adjacent to the STI layer during formation of the groove on the surface of the semiconductor substrate;
the etching step being a step of removing the semiconductor burrs by dry etching using, as the etching gas, a mixed gas having a gas flow rate ratio such that an etch rate ratio R1/R2 is smaller than 1, where R1 is the etch rate in the depth direction in a section of the groove in a direction parallel to word lines and R2 is the etch rate in the lateral direction in the section of the groove in the direction parallel to the word lines;
the mixed gas consisting essentially of SF₆ and SiF₄.

4. The method according to claim 2, wherein:
the etching step is a step intended to remove semiconductor burrs produced in the groove on groove surfaces adjacent to the STI layer during formation of the groove on the surface of the semiconductor substrate;
the etching step being a step of removing the semiconductor burrs by dry etching using, as the etching gas, a mixed gas having a gas flow rate ratio such that an etch rate ratio R1/R2 is smaller than 1, where R1 is the etch rate in the depth direction in a section of the groove in a direction parallel to word lines and R2 is the etch rate in the lateral direction in the section of the groove in the direction parallel to the word lines and that an etch rate ratio R3/R4 is equal to or greater than 1, where R3 represents an etch rate in a depth direction in a section of the groove in a direction perpendicular to the word lines and R4 represents an etch rate in a lateral direction in the section of the groove in the direction perpendicular to the word lines;
the mixed gas consisting essentially of SF₆ and SiF₄.

5. A method of producing a semiconductor device, comprising a STI (Shallow Trench Isolation) forming step of forming a STI layer on a surface of a semiconductor substrate and a groove forming step of forming a groove for a trench gate by dry etching on the surface of the semiconductor substrate in an area surrounded by the STI layer, wherein:
the groove forming step is a step of forming the groove in the area by dry etching using a mixed gas consisting essentially of SF₆ and HBr without producing semiconductor burrs in the groove on groove surfaces adjacent to the STI layer.

6. The method according to claim 5, wherein the groove forming step uses, as the mixed gas, a mixed gas having a gas flow rate ratio FR satisfying:
0.2<FR<4
where FR is given by (SF₆ flow rate)/(HBr flow rate).
